(19) United States
(12) Patent Application Publication
(10) Pub. No.: US 2010/0213517 A1
(43) Pub. Date: Aug. 26, 2010

(54) HIGH VOLTAGE SEMICONDUCTOR DEVICE

(75) Inventors: JAN Sonsky, Leuven (BE); Anco Heringa, Waalre (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/738,370

(22) PCT Filed: Oct. 16, 2008
(86) PCT No.: PCT/IB08/54256

§ 371 Date: Apr. 16, 2010

(30) Foreign Application Priority Data
Oct. 19, 2007 (EP) 07118840.3
Oct. 16, 2008 (IB) PCT/IB2008/054256

(51) Int. Cl. H01L 29/78; H01L 21/762

(52) U.S. Cl. 257/288; 438/149; 257/E21.561; 257/E29.255

(57) ABSTRACT

This invention describes implementation of medium/high voltage semiconductor devices with a better voltage-blocking capability versus specific on-resistanσe trade off. This approach can be implemented in baseline and submicron CMOS without any additional process steps. Said devices comprise dielectric regions and semiconductor regions formed between them. Conductive extentions are formed on the dielectric regions, said extentions interacting capacitively with the semiconducter regions.

### FIELD OF THE INVENTION

This invention describes implementation of medium/high voltage semiconductor devices with a better voltage-blocking capability versus specific on-resistance trade off. This approach can be implemented in baseline and submicron CMOS without any additional process steps.

### BACKGROUND OF THE INVENTION

CMOS semiconductor devices, such as transistors, are known. Typically these devices have only limited applicability in high voltage (HV) due to for instance breakdown of voltage.

Many IC (Integrated Circuit) applications require for instance power management units for DC:DC down- or up-conversion of the supply voltage. Typically NMOS and PMOS semiconductor devices, such as transistors, with capability from 5V up to 25 V are required for such applications.

Furthermore, applications such as solid-state lighting, power amplifiers and MEMS sensor or actuator driving circuits require transistors capable of handling voltages up to 50 V or even higher operating voltages. Integration of such in this respect so-called high voltage transistors in modern CMOS processes is a problem, because typically it cannot be done in a cost-competitive way which would be very attractive. Such integration leads to overall system miniaturization, reduces cost and improves quality risk.

The traditional solutions for such an integration are based on adding masks and process steps in the CMOS process flow. Usually the steps comprise low-dose implantations, to enable the high voltage functionality. These implantations results in higher process complexity and higher cost per chip area.

Such solutions feature only a moderate on-resistance (Rds-on), key parameter of high voltage transistors, which determines total area of HV device necessary to provide required current. The lower the Rds-on for given breakdown voltage, the better the quality of HV device. The Rds-on significantly increases with a breakdown voltage (e.g. Rds-on˜BV^{2.5}). Further optimization of the Rds-on versus breakdown voltage trade-off in high voltage devices can be achieved through lateral field plates in a dielectric stack or vertically in trenches. In both cases additional specific process steps that are non-standard in CMOS have to be used. This results in more complex and expensive CMOS process and requires additional process (re-) qualification, which delays introduction of new products in advanced CMOS processes.

Recently applicants have successfully demonstrated a different approach, where dedicated “active” or STI (shallow trench isolation) layout enabled high voltages without additional process steps. This cost free approach provides devices with similar performance (on-resistance vs. breakdown voltage trade-off) as the traditional solutions.

However, it would be quite attractive, if a cost-free, layout-enabled approach could be further improved to also enhance the device performance giving better on-resistance vs. breakdown voltage as compared to prior art solutions.

Thus, the prior art semiconductor devices are limited in applicability, amongst others due to one or more of problems associated with relatively poor on-resistance vs. breakdown voltage trade-off, high costs due to extra processing steps and/or masks, risks of failure of the device.

It is an aim of the present invention to overcome one or more of the above-mentioned problems.

Surprisingly the applicants have invented a novel architecture of a semiconductor device, which novel device overcomes one or more of the above mentioned problems.

### SUMMARY OF THE INVENTION

The present invention relates to a semiconductor device for use in high voltage application, comprising at least one dielectric in substrate region, preferably an STI region, one or more semiconductor regions located between the at least one dielectric region, one or more electrically conductive extensions in a lateral plane, placed on and extending over the at least one dielectric region, wherein the one or more extensions capacitevely interact with the one or more semiconductor regions through a part of the dielectric region between the extension edge and the dielectric edge, a method of manufacturing said device, use thereof and device comprise the semiconductor device.

### DETAILED DESCRIPTION OF THE INVENTION

In a first aspect the present invention relates to a semiconductor device for use in high voltage application, comprising at least one dielectric in substrate region, preferably an STI region, one or more semiconductor regions located between the at least one dielectric region, one or more electrically conductive extensions in a lateral plane, placed on and extending over the at least one dielectric region, wherein the one or more extensions capacitevely interact with the one or more semiconductor regions through a part of the dielectric region between the extension edge and the dielectric edge.

These conductive extensions are most conveniently realized in IC processes as gate (doped polysilicon) extensions, also called gate fingers, polysilicon fingers, gate field plates or polysilicon field plates in the further description.

The semiconductor device is especially applicable in many CMOS processes, especially in deep submicron CMOS processes. Modern CMOS processes allow mask details, namely in active (STI) and POLY (gate) masks, that can be conveniently exploited for high voltage implementation according to the embodiments of this invention. For example implementation of the present invention in a standard 65 nm CMOS process shows that substantially higher (for example 3 times) extension doping or substantially better active-to-STI width ratio (in the prior invention of applicants) can be used, using said field plates. This enhances the Rds-on versus breakdown Figure of merit substantially (for example up to 2 times).

In a preferred embodiment the device is a transistor, a diode, a bipolar transistor, a MOSFET, or an IGBT.

Examples of the proposed construction of the extended-drain region are given for an NMOS transistor, but are equally applicable to a PMOS transistor. A similar construction can be applied to other electronic devices, such as diodes, bipolar transistors, MOSFETS, IGBT's, giving improvements in breakdown voltage versus doping (=resistance) trade-offs, e.g. in bipolar transistor to enhance collector breakdown voltage.

In the case of a diode, the device does not comprise a gate, but one or more polysilicon field plates.

The present semiconductor device may comprise a transistor. Typically a transistor comprises a gate, a source and a drain, as is well known in IC-technology.

The drain may further comprise an extended drain, in order to improve the characteristics of the transistor, with respect to high voltage applicability.

In advanced IC-technology each transistor is typically surrounded by a dielectric region such as a shallow trench isolation (STI). This is also a well-known feature in advanced IC-technology that allows isolation of individual transistors.

It is noted that source and drain regions are typically doped with N-type or P-type dopands for an NMOS or PMOS transistor, respectively. The person skilled in the art will realize that the high voltage-supporting region can be equally well applied into other type of transistors, for example bipolar transistors. The gate comprises one or more extensions in a lateral plane, as is for instance indicated in FIG. 1. These extensions are also referred to as “gate fingers”.

These extensions extend from the gate towards the drain region. It is noted that the extensions need not be connected to the gate within the lateral plane thereof, as is indicated in FIG. 4b. It is further noticed that the relative positions of the extension(s), gate, source and drain may vary, with respect to one and another.

Typically, depending on applied CMOS technology, the gate dielectric is formed from oxide, typically silicon oxide, wherein the thickness of the gate oxide is in the order of 1-15 nm. Of course the gate dielectric, may be formed from any other dielectric material, which is applicable in the CMOS technology.

The gate electrode and its extension are typically formed by conductive polysilicon with a typical thickness in a range from 50 to 200 nm. Obviously, any other conductive material that is practiced in CMOS technology is applicable.

The gate extensions would typically have the same thickness and would be formed from the same material as the gate itself, for reasons of ease of processability.

However, it is possible to manufacture the gate fingers (extension) using a conductive material different from the gate electrode material, in terms of material composition or thickness. A practical example is application of heavily N+ doped gate fingers in case of a drain extended PMOS transistor. The gate electrode of a PMOS transistor is typically heavily P+ doped and salicided to improve the resistance. Contrary to most obvious implementations, the gate extensions may be heavily N+ doped, and the silicidation may be omitted.

Thus, the present invention discloses implementation of medium/high voltage semiconductor devices, such as transistors, with gate fingers positioned on dielectric regions, such as STI regions, stretched along extended drain regions. It is believed, without wishing to be bound by theory, that these gate fingers are capacitively coupled to the extended drain region through the underlying dielectric, such as STI, region sides, separating the gate fingers laterally from the extended drain regions. The surprising effect thereof is that coupling induces enhanced depletion of the extended-drain region, and thus e.g. a better voltage-blocking capability versus specific on-resistance trade off. This capacitive coupling effect depends critically on the precise distance between the gate extension and the edge of dielectric, such as STI, region, since this lateral dimension effectively represents a thickness of the capacitor. This distance may be determined on a case by case basis.

A further advantage is that this approach can be implemented in a baseline and preferably in a deep submicron CMOS process without any additional process steps.

The present invention finds application in high-voltage and high power devices and circuits integrated in modern CMOS technologies, e.g. power management units, solid-state lighting, power amplifiers, MEMS drives and display drivers.

The present invention provides amongst others the following advantages:

a cost-free implementation of high voltage capability in any CMOS technology,

a better breakdown voltage vs. on-resistance trade-off with respect to traditional solutions,

an improved safe-operating-area,

an improved reliability, and

a device such as a transistor with high gate-voltage capability.

The present device, is in the case of a transistor for instance an extended-drain transistor with STI (shallow trench isolation) region placed along the extended-drain region, where gate-fingers are placed on top the STI regions (see FIG. 1a). These gate-fingers may either be connected with the MOSFET-gate or be connected independently with a fixed potential, e.g. the source potential, during the operation. It is believed that the capacitive coupling of these gate-fingers to the extended-drain region through the part of the STI regions results in enhanced depletion of the extended-drain region. This allows a better extended drain resistance/allowed drain voltage trade-off e.g. a higher extended drain doping at the same voltage blocking capability or a higher voltage-blocking capability at the same extended drain doping.

It is believed that the capacitive coupling effect is determined by the distance between the gate-fingers and the STI edge, which can be very accurately determined by positioning the gate-fingers (the STI and gate masks allow the finest patterns in modern CMOS). Shorter distance will boost the capacitive coupling, but eventually will lead to early breakdown across the STI regions.

In a preferred embodiment the present semiconductor device comprises one or more extensions, wherein the extension is in the form of a rectangular layer or in the form of a in a direction perpendicular to the extension tapered layer, wherein the tapered layer is smaller in the drain region.

As the gate-fingers are located on top of the dielectric, such as STI, regions, the capacitive coupling decreases at greater depth (see FIG. 1b). As the extended-drain region is formed by implantation, the upper part is more highly doped and the doping concentration reduces in depth. This is favourable for the coupling effect, as stronger coupling is required in the upper portion, while weaker coupling is tolerable at greater depth. Anyway it is therefore preferred to have the extended-drain region formed by relatively shallow implantation.

The present device can be further optimized by patterning (tapering) the gate-fingers, so that the gate-fingers are located closer to the dielectric, such as STI, edge (i.e. shorter distance and thus stronger capacitive coupling) at the gate side. The gate-fingers can be located further apart from the dielectric, such as STI, edge (i.e. longer distance and thus weaker capacitive coupling, but not limiting the breakdown voltage across the dielectric, such as STI, oxide) at the drain side. This embodiment is illustrated in FIG. 2.

In a preferred embodiment the present semiconductor device comprises one or more extensions, wherein the dielectric, such as STI, region is tapered perpendicular to the extension, wherein the tapered dielectric, such as STI, region is smaller in the drain region.

Thus, the extended-drain region can also be tapered, so that its width is relatively smaller at the gate side and wider at the drain side. Such an arrangement results in grading the effective (integral) doping along the extended-drain region, i.e. less doping dose on the gate-channel side and higher doping dose near the drain. This embodiment is illustrated in FIG. 3. FIG. 3 shows a top view of an NMOS transistor with gate-fingers on STI and a tapered extended-drain region width. The distance between the gate-fingers and the STI edge can be constant or can vary.

In a preferred embodiment the present semiconductor device comprises one or more extensions, wherein the extension is integral with the gate, or wherein the extension is connected to the source or to another independent voltage terminal.

Thus, the gate-fingers can be integral with the gates (being interconnected) or they can be separated from the gates. In the latter case the gate-fingers can be connected to the source terminal or an independent terminal. Thus, the voltage of the gate can be tailored. The arrangement with the gate fingers connected with source or another constant voltage is particularly attractive for fast (low capacitance) switching. These embodiments are illustrated in FIG. 4a,b.

FIG. 4 shows a top view of NMOS transistors with integral gate-fingers (a) and isolated gate-fingers (b). The crossed box indicates contact to the gate-fingers. Although the contacts on the gate fingers are indicated near the drain side, they can be located anywhere along the gate finger length.

The gate-fingers can extend either along a major part of the extended-drain region or along only a small part of the extended-drain region (see FIG. 5a,b). The latter is particularly applicable to reduce hot carrier effects and thus improve device ruggedness and reliability because reduction of the field at the end of the channel at the gate edge is essential for avoidance of hot-carrier effects.

FIG. 5 shows a top view of NMMOS transistors with long (a) and short (b) gate-fingers on STI.

It is noted that an NMOS transistor was illustrated in the previous Figures, but the proposed construction of the extended-drain region is equally applicable to PMOS transistor. A similar construction can be applied to other electronic devices, such as diodes, bipolar transistors, IGBT's giving improvements in breakdown voltage versus doping (i.e. resistance) trade-offs, e.g. in bipolar transistor to enhance collector breakdown voltage. An example of a high voltage bipolar transistor with an extended collector is also given below. In a further embodiment the semiconductor device according to the invention relates to the arrangement of cells as mentioned above according to the invention into an array with additional electrically conductive extensions placed on the outsides on the surrounding dielectric region.

FIG. 6 shows a top view of an NMOS transistor with individual cells grouped into an array. A single transistor cell is shown in (a). To increase the overall width (i.e. drive current) the cell has to be replicated into an array (b). However the symmetry of the gate fingers is lost on the outside edges of such array. As the drain-extended region on the upper and lower outside edge is affected by only 1 (inside) gate finger, the capacitive coupling effect will be different (lower) than the effect in the internal portions of the array. This will result in an early breakdown voltage there. In order to guarantee identical capacitive effects and hence identical breakdown voltage, additional gate fingers should be placed on the outside of the structure on top of the surrounding STI region. Such structure is usually refer to as a edge termination. This is illustrated in FIG. 6.

In a further embodiment the semiconductor device according to the invention relates to a device, wherein the semiconductor regions comprise a gate, a drain, a source, optionally an extended drain channel, and dielectric in substrate region, preferably an STI region, wherein the gate is formed on the dielectric region and is separated from the semiconductor regions through a part of the dielectric region, located between a gate edge and one or more opposing semiconductor region edges.

We have used this concept to realize a high gate voltage capability. Such a high gate-voltage NMOS transistor is shown in FIG. 7a. Here the gate-fingers are used as actual gates and the STI oxide separating them from silicon acts as the gate oxide. The gate oxide “thickness” is determined by the distance of the gate-fingers from the STI edge. Such a transistor (cell) will withstand high voltage on the gate terminal, but it will have a relatively small drive current. Multiple cells can be arranged in an array to get the required output drive current (FIG. 7b).

In a second aspect the present invention relates to a method of producing a semiconductor device according to the present invention, comprising:
providing P-type or N-type doped semiconductor substrate, respectively
forming dielectric regions in substrate, such as trenches filled with dielectric in said substrate, forming trench regions,

implanting a drain and optionally an extended drain region using N- or P-type dopant, respectively, wherein the depth of such region is preferably equal or smaller then the depth of the dielectric regions, wherein the dopant type of the extended drain region is identical to that of the drain region, but preferably has a relatively lower dose,

forming a doped P-type or N-type well, respectively,

forming a gate structure on the doped substrate, which structure comprises extensions on the trench regions,

optionally forming shallow N-type or P-type doped source and drain regions, respectively,

optionally forming spacers around the gate structure,

implanting a high dose of N-type or P-type dopand into the source and drain, respectively,

implanting a high dose of P-type or N-type dopand next to the source to contact the P-well or N-well region, respectively, and

optionally forming a silicide on the source, gate and drain region, optionally on the gate extensions, but not on the drain extensions.

Normal bulk substrate or SOI substrates can be equally well used.

In a further aspect the present invention relates to the use of a semiconductor device according to the invention, in a high voltage application, such as wherein more than nominal voltage is required, such as more than 2.5 V, preferably more than 10 V.

In yet a further aspect the present invention relates to the use of enhanced gate structures, preferably positioned on a dielectric region, such as an STI region, preferably stretched along extended drain regions, for capacitively coupling thereof through the underlying dielectric region to the extended drain regions. Advantages thereof are give above.

In a further aspect the present invention relates to the use of capacitive effect of a gate itself in a transistor according to the invention. Advantages thereof are giving above.

In another aspect the present invention relates to the use of a semiconductor device according to the invention, in a chip, in a voltage regulator, DC:DC converter, memory driving circuits, in solid-state lighting, in a power amplifier, in a MEMS driving circuit, in a transistor, in a diode, in a MOSFET, in an IGBT, and combinations thereof.

In another aspect the present invention relates to devices, such as a chip, a voltage regulator, a DC:DC converter, memory driving circuits, solid-state lighting, a power amplifier, a MEMS driving circuit, a transistor, a diode, a MOSFET, an IGBT, and combinations thereof, comprising a semiconductor device according to the invention.

In another aspect the present invention relates to a semiconductor device according to the invention, or method according to the invention, or use according to the invention, or device according to the invention, wherein the dielectric regions in substrate are shallow trench isolation (STI) regions.

The present invention is further elucidated by the following Figures and examples, which are not intended to limit the scope of the invention. The person skilled in the art will understand that various embodiments may be combined.

### BRIEF DESCRIPTION OF THE DRAWINGS

FIG. 1 shows an NMOS transistor with gate fingers and cross sections thereof.

FIG. 2 shows an NMOS transistor with tapered gate fingers.

FIG. 3 shows an NMOS transistor with tapered gate fingers and tapered STI regions.

FIG. 4 shows an NMOS transistor with integrated and isolated gate fingers.

FIG. 5 shows an NMOS transistor with long and short gate fingers.

FIG. 6 shows an NMOS transistors with individual cells grouped into array and the edge termination area on the outside to form edge termination.

FIG. 7 shows an NMOS transistor cell and an array thereof for a high-gate voltage capability.

FIG. 8 shows a diode.

FIG. 9 shows a bipolar transistor.

FIG. 10 shows a process flow for manufacturing an NMOS transistor with gate fingers.

### DETAILED DESCRIPTION OF THE DRAWINGS

In detail the Figures show the following.

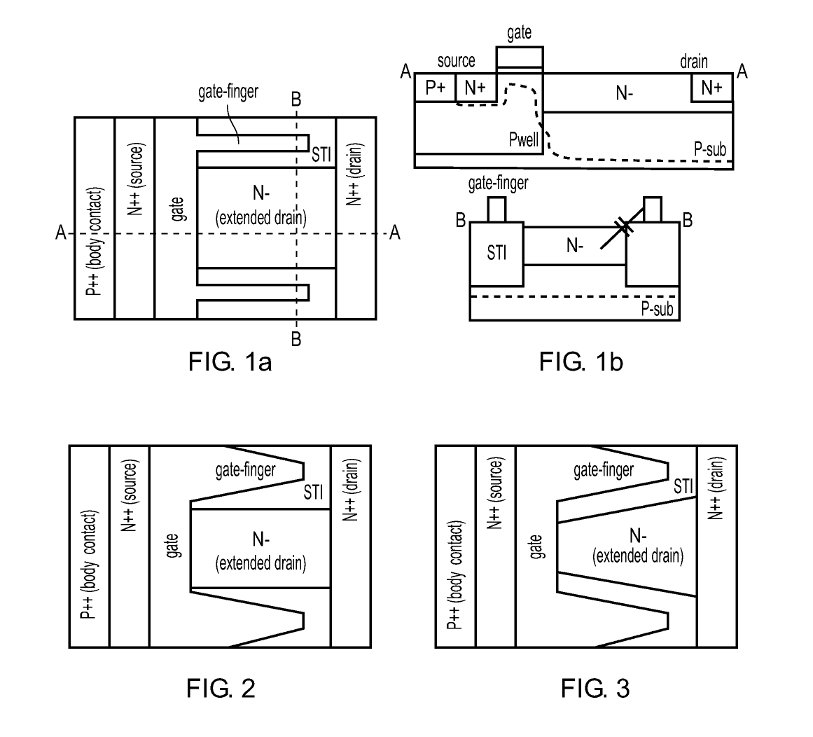

In FIG. 1a a top view of a high voltage NMOS transistor is shown. The source, drain and gate form standard components of a transistor. Underneath the gate and source a Pwell implantation has taken place. The source has an N++ implantation and a P+ body contact. The drain is N+ doped. Between the drain and a gate, a lightly doped N− region, functioning as extended drain, is present. Underneath the drain area a P-doped region is present. The gate has extensions extending over an STI region. Not shown are the STI-regions for peripheral isolation to the left and right of the Figure, and the substrate, to the bottom, typically Si. The layers above the transistor, typically formed of different metallization levels and inter-metal dielectric passivation layers, are omitted for sake of simplicity. Cross-sections A-A and B-B are provided in FIGS. 1b and 1c, respectively. Therein, the dashed lines indicate the depletion region. The extended drain region may be fully depleted at high voltage applied between drain and source.

FIG. 2 shows a similar structure as FIG. 1a, wherein the gate finger is now in a tapered form. With tapered any form whereof the width that is broader at the gate side compared to the width at the drain side is meant. Thus for example triangular forms, tapered forms, parallelopipida, two sided stair-like structures, as well as combinations thereof, are envisaged.

FIG. 3 shows a top view of an NMOS transistor, with gate-fingers on STI and a tapered extended-drain region width. As a consequence the gate finger is tapered identically. The distance between the gate-fingers and the STI edge along the drain extension region can be constant or can vary, so that the distance is shorter near gate and wider near drain.

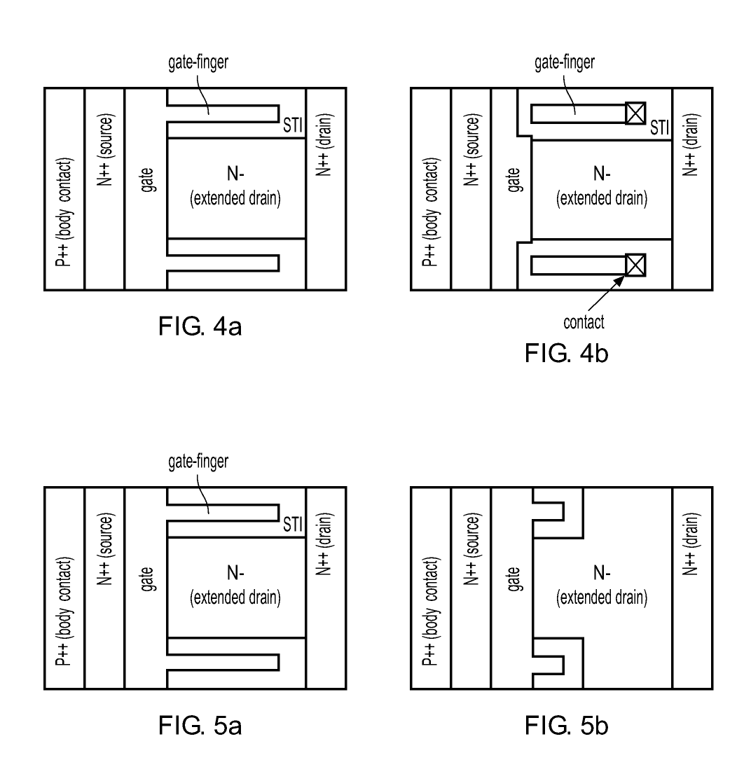

FIG. 4 shows a top view of NMMOS transistors with integral gate-fingers (a) and isolated gate-fingers (b). The crossed box indicates contact to the gate-fingers.

FIG. 5 shows a top view of NMOS transistors with long (a) and short (b) gate-fingers on STI, respectively.

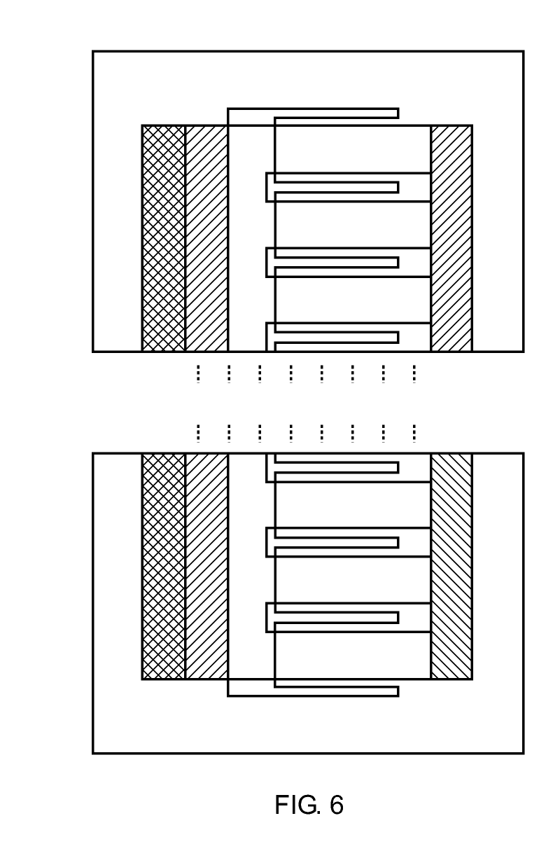

FIG. 6 shows an NMOS transistors with individual cells grouped into array and the edge termination area on the outsides.

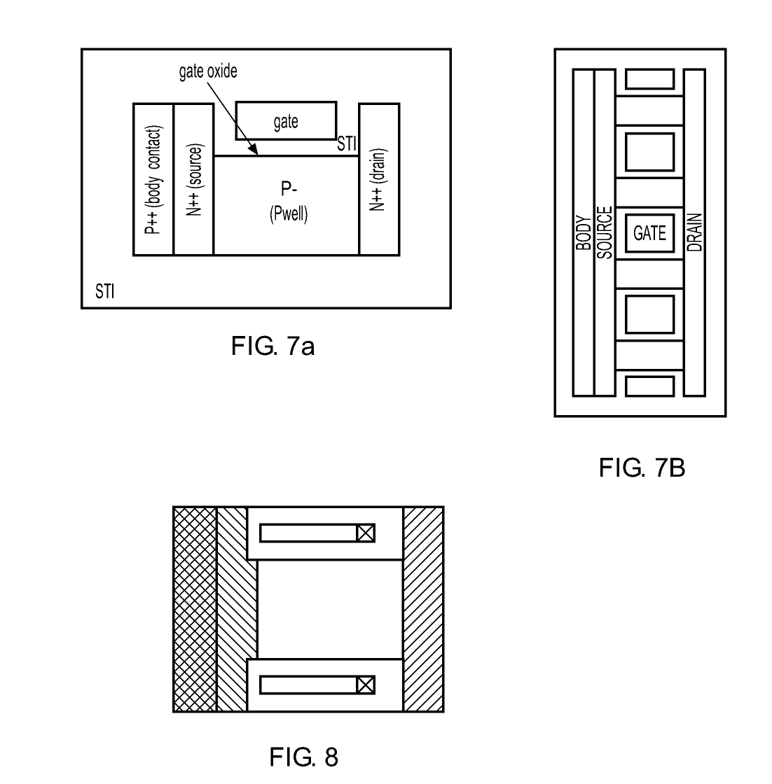

FIG. 7 shows a top view of an NMOS transistor for high gate-voltage application. A single transistor cell is shown in (a). To increase the overall width (i.e. drive current) the cell has to be replicated into an array (b), respectively.

FIG. 8 shows a top view of body diode. The gate and source were simply removed. The gate fingers are connected through metal lines to a body P+ contact.

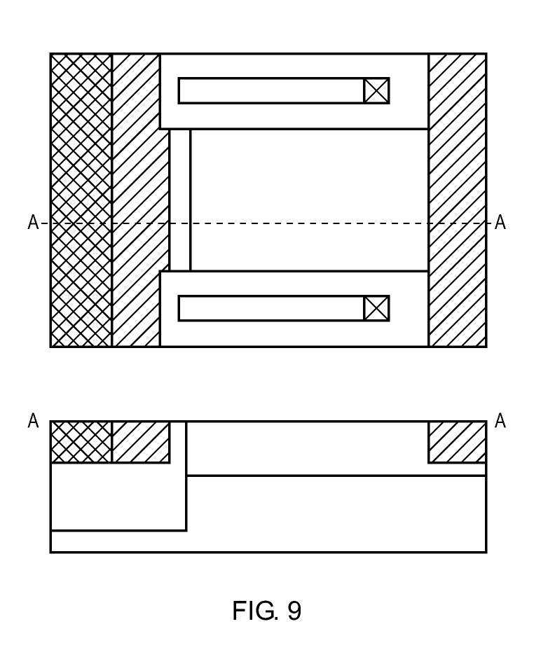

FIG. 9 shows a bipolar transistor.

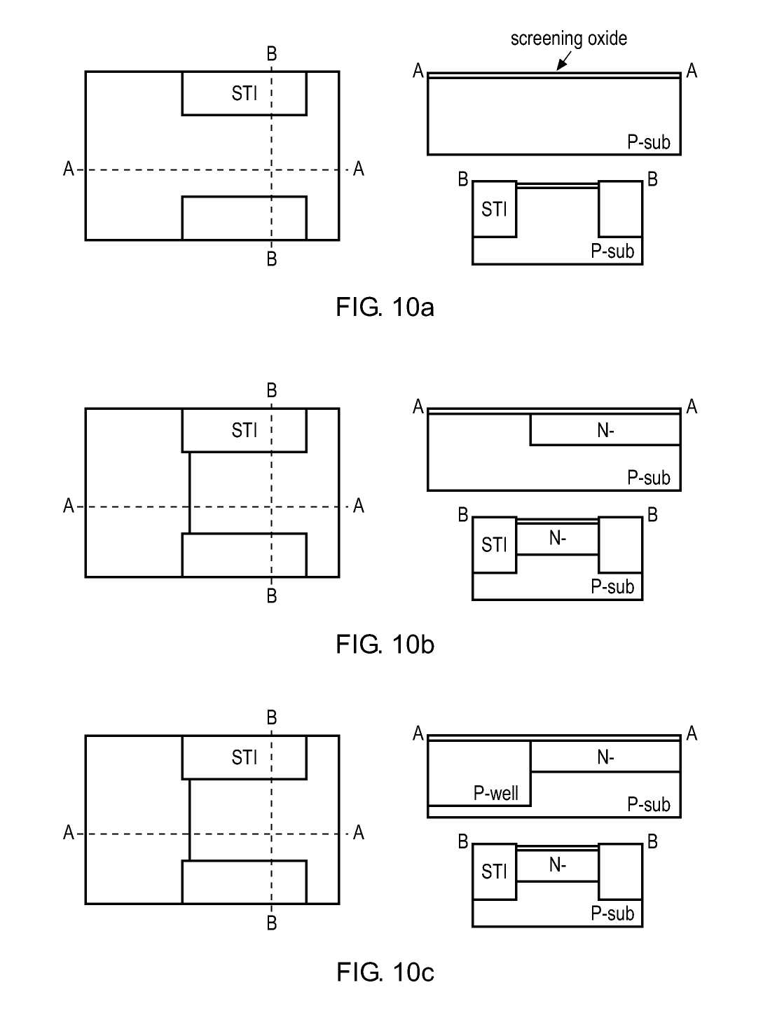

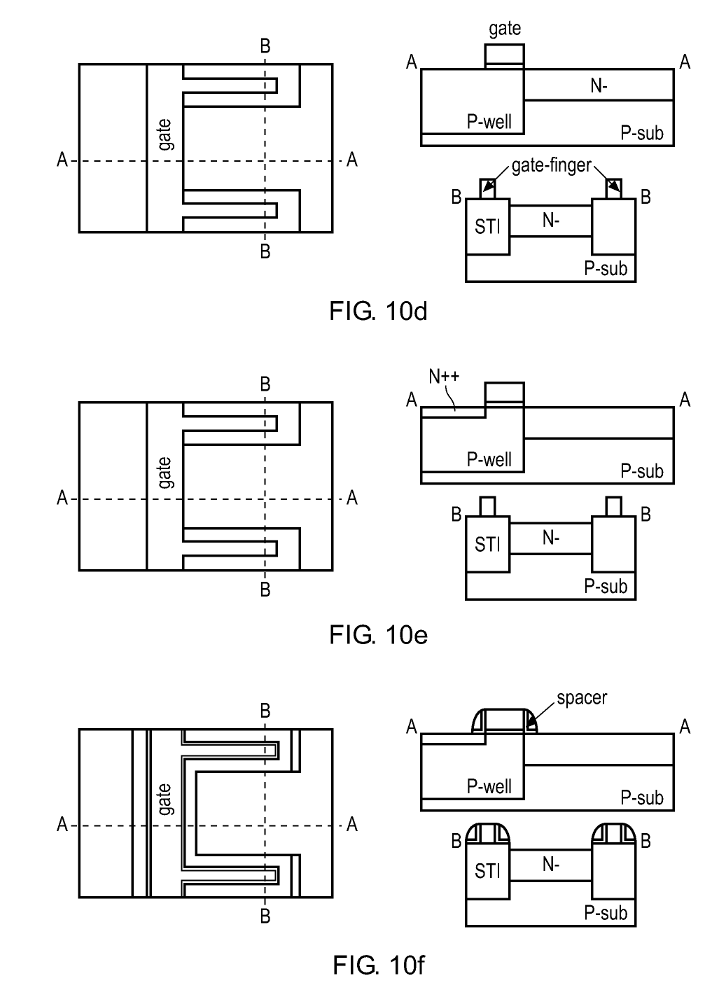

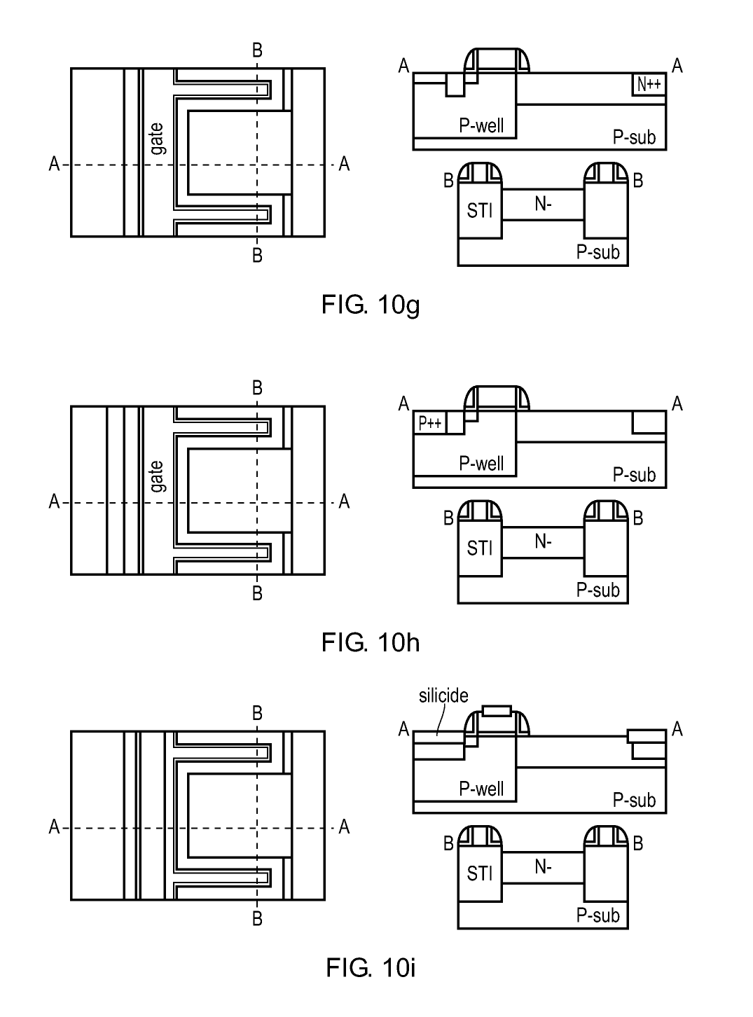

FIG. 10 shows a process flow, given a detailed description of how to manufacture the present device in a CMOS process.

The disclosed devices are fabricated within standard CMOS process on bulk or SOI wafers. This is a well-known technology. Purely for completeness and example, the NMOS transistor with gate-fingers on STI (see FIG. 1a) will be described at different stages of a CMOS processing.

FIG. 10 shows in all cases a top view of an example of the present architecture. Further, in each case two cross sections A-A and B-B, respectively, are provided.

FIG. 10a. shows an STI module comprising oxide/nitride deposition, followed by a lithography step, a trench etch step, an oxide filling step, a planarization step and nitride wet etch step.

FIG. 10b. shows an extended-drain region implantation, comprising a lithography step, followed by a low dose Phosphorus or Arsenic implantation, respectively.

FIG. 10c. shows a Pwell module, comprising a lithography step, followed by a Boron implantation.

FIG. 10d. shows a gate stack module, comprising a screening oxide removal step, an oxidation step, a poly-Si deposition step and a patterning step.

FIG. 10e. shows an NLDD module, comprising a lithography step, a shallow and a high dose Phosphorus or Arsenic implantation step, and an optionally pockets implant step (in order to better control short-channel effects) are also done here (shallow and high tilted Boron implant).

FIG. 10f. shows a spacer module, comprising for example an oxide/nitride deposition step and a spacer etch step.

FIG. 10g. shows a N++ module, comprising a source/drain implant step (high dose and shallow Arsenic or Phosphorus implantation using photoresist mask).

FIG. 10h. shows a P++ module, comprising a body-contact implant step (high dose and shallow Boron implantation using photoresist mask).

FIG. 10i. shows a local silicide module, comprising a silicidation step using a mask to protect the extended-drain region.

These steps typically are followed by standard back-end-of-the-line processing, in order to form a complete IC.

The person skilled in the art will understand that the above is a schematic outline, for forming the present semiconductor device. Therein rather standard process modules are used, such as those disclosed in the standard literature.

The person skilled in the art will also realize that the invention is equally applicable to different type of substrate, standard bulk substrates, thick or thin SOI substrate, or any other semiconductor substrate including SiGe, Ge or other III-V materials. In case of SOI wafers, the STI trenches may be shallower then the thickness of SOI material. The STI trenches may be filled with other dielectric materials such as air, silicon nitride, or other dielectric materials with a higher dielectric constant. The gate fingers can be formed by any conductive material such as variety of metals. The proposed device concept can be applied in a variety of semiconductor IC processes included CMOS, BiCMOS or smart power technologies. The transistors according to this invention may be also processed individually as discrete components.

1. Semiconductor device for use in high gate voltage application, comprising:
at least one dielectric in substrate region.
one or more semiconductor regions located between the at least one dielectric region,
one or more electrically conductive extensions in a lateral plane, placed on and extending over the at least one dielectric region,
wherein the one or more extensions capacitively interact with the one or more semiconductor regions through a part of the dielectric region between the extension edge and the dielectric edge.

2. Semiconductor device according to claim 1, wherein the device is a transistor, a diode, a bipolar transistor, a MOSFET, or an IGBT.

3. Semiconductor device according to claim 1, comprising a transistor, which transistor comprises a gate, a source, a drain and optionally an extended drain.

4. Semiconductor device according to claim 1, wherein the electrically conductive extension is in the form of a rectangular layer or in the form of a in a direction perpendicular to the extension tapered layer, wherein the tapered layer is smaller in the drain region.

5. Semiconductor device according claim 1, wherein the dielectric region is tapered perpendicular to the extension, wherein the tapered dielectric region is smaller in the drain region.

6. Semiconductor device according to claim 1, wherein the electrically conductive extension is integral with the gate, or wherein the extension is connected to a source or to another independent voltage terminal.

7. Semiconductor device composed of cells according to claim 1 into an array with additional electrically conductive extensions placed on the outsides on the surrounding dielectric region.

8. Semiconductor device for use in high gate voltage application according to claim 1,
wherein the semiconductor regions comprise a gate, a drain, a source, optionally an extended drain channel, and dielectric in substrate region,
wherein the gate is formed on the dielectric region and is separated from the semiconductor regions through a part of the dielectric region, located between a gate edge and one or more opposing semiconductor region edges.

9. A method of producing a semiconductor device, comprising the steps of:
providing P-type or N-type doped semiconductor substrate, respectively,
forming dielectric regions in substrate, such as trenches filled with dielectric in said substrate, forming trench regions,
implanting a drain and optionally an extended drain region using N- or P-type dopant, respectively, wherein the depth of such region is equal or smaller then the depth of the dielectric regions, wherein the dopant type of the extended drain region is identical to that of the drain region,
wherein the dopant dose of the extended drain region is less than or equal to that of the drain region,
forming a doped P-type or N-type well, respectively,
forming a gate structure on the doped substrate, which structure comprises extensions on the trench regions,
optionally forming shallow N-type or P-type doped source and drain regions, respectively,
optionally forming spacers around the gate structure,
implanting a high dose of N-type or P-type dopant into the source and drain, respectively,
implanting a high dose of P-type or N-type dopand next to the source to contact the P-well or N-well region, respectively, and
optionally forming a silicide on the source, gate and drain region, optionally on the gate extensions, but not on the drain extensions.

10. Method according to claim 9, wherein the substrate is an SOI wafer.

11. The semiconductor device according to claim 1, wherein the semiconductor device functions, in a high voltage application, such as wherein more than nominal voltage is required, such as more than 1V, preferably more than 10 V.

12. The semiconductor device according to claim 1, wherein the device functions as enhanced gate structures, positioned on a dielectric region, stretched along extended drain regions, for capacitively coupling thereof through the underlying dielectric region to the extended drain regions.

13. The semiconductor device according to claim 1, wherein the device functions in a capacitive effect of a gate itself in a transistor.

14. The semiconductor device according to claim 1, wherein the semiconductor device functions, in a chip, in a voltage regulator, DC:DC converter, memory driving circuits, in solid-state lighting, in a power amplifier, in a MEMS driving circuit, in a transistor, in a diode, in a MOSFET, in an IGBT, and combinations thereof.

15. A device, such as a chip, a voltage supply, a DC:DC converter, a memory driving circuits, a solid-state lighting, a power amplifier, a MEMS driving circuit, a transistor, a diode, a MOSFET, an IGBT, and combinations thereof, comprising a semiconductor device according to claim 1.

16. The semiconductor device according to claim 1, wherein the dielectric regions in substrate are shallow trench isolation (STI) regions.

17. The semiconductor device according to claim 8, wherein the dielectric regions in substrate are shallow trench isolation (STI) regions.

18. The method according to claim 9, wherein the dielectric regions in substrate are shallow trench isolation (STI) regions.

19. The method according to claim 14, wherein the dielectric regions in substrate are shallow trench isolation (STI) regions.

20. The method according to claim 15, wherein the dielectric regions in substrate are shallow trench isolation (STI) regions.
